(19) United States
(12) Patent Application Publication
(10) Pub. No.: US 2023/0019369 A1
(43) Pub. Date: Jan. 19, 2023

(54) PLASMA PROCESSING APPARATUS

(71) Applicant: Tokyo Electron Limited, Tokyo (JP)

(72) Inventors: Masaki HIRAYAMA, Fuchu City (JP); Toshifumi KITAHARA, Fuchu City (JP)

(21) Appl. No.: 17/809,446

(22) Filed: Jun. 28, 2022

(30) Foreign Application Priority Data
Jul. 7, 2021 (JP) 2021-112600
Dec. 10, 2021 (JP) 2021-201019
Jan. 7, 2022 (JP) 2022-001465

(51) Int. Cl. H01J 37/32

(52) U.S. Cl. CPC H01J 37/32651; H01J 37/32082; H01J 37/32834

(57) ABSTRACT

A plasma processing apparatus includes: a chamber; an introducer installed such that electromagnetic waves are introduced into the chamber from the introducer; and a choke structure installed on a wall of the chamber and configured to suppress propagation of the electromagnetic waves downstream along an inner wall surface of the chamber from a location at which the choke structure is installed. The choke structure includes: a first portion having a slit shape and connected to a space within the chamber; and a second portion extending from the first portion in the wall of the chamber. A length of the second portion along a direction of an electric field of the electromagnetic waves in the second portion is longer than a length of the first portion along a direction of an electric field of the electromagnetic waves in the first portion.

### CROSS-REFERENCE TO RELATED APPLICATIONS

This application is based upon and claims the benefit of priority from Japanese Patent Application Nos. 2021-112600, 2021-201019, and 2022-001465, filed on Jul. 7, 2021, Dec. 10, 2021, and Jan. 7, 2022, respectively, the entire contents of which are incorporated herein by reference.

### TECHNICAL FIELD

An exemplary embodiment of the present disclosure relates to a plasma processing apparatus.

### BACKGROUND

A plasma processing apparatus is used in plasma processing of a substrate. A type of plasma processing apparatus is described in Patent Document 1 below. The plasma processing apparatus described in Patent Document 1 uses radio-frequency waves in the UHF band or VHF band as electromagnetic waves for exciting plasma. The electromagnetic waves introduced into the chamber propagate as surface waves along the wall surface within the chamber. The plasma processing apparatus described in Patent Document 1 has a choke part in order to suppress the propagation of electromagnetic waves to unnecessary locations within the chamber.

### PRIOR ART DOCUMENT

### Patent Document

Patent Document 1: International Publication No. WO 2018/101065

### SUMMARY

According to one embodiment of the present disclosure, there is provided a plasma processing apparatus. The plasma processing apparatus includes a chamber, an introducer, and a choke structure. The introducer is installed such that electromagnetic waves are introduced into the chamber from the introducer. The choke structure is installed on the wall of the chamber. The choke structure is configured to suppress the propagation of electromagnetic waves downstream along the inner wall of the chamber from a location at which the chock structure is installed. The choke structure includes a slit-shaped first portion and a second portion. The first portion is connected to the space within the chamber. The second portion extends from the first portion in the wall of the chamber. The length of the second portion along a direction of an electric field of the electromagnetic waves in the second portion is longer than the length of the first portion along a direction of an electric field of the electromagnetic waves in the first portion.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view schematically illustrating a plasma processing apparatus according to an exemplary embodiment.

FIG. 2 is a partially enlarged cross-sectional view of a choke structure in a plasma processing apparatus according to an exemplary embodiment.

FIG. 3 is a view schematically illustrating a plasma processing apparatus according to another exemplary embodiment.

FIG. 4 is a cutaway perspective view illustrating an example of an insulative member, which may be adopted in the plasma processing apparatus illustrated in FIG. 3.

FIG. 5 is a cutaway perspective view illustrating another example of an insulative member, which may be adopted in the plasma processing apparatus illustrated in FIG. 3.

FIG. 6 is a view schematically illustrating a plasma processing apparatus according to still another exemplary embodiment.

FIG. 7 is a view schematically illustrating a plasma processing apparatus according to still another exemplary embodiment.

FIG. 8 is a cutaway perspective view illustrating an example of a dielectric portion, an insulative member, and an elastic ring that may be adopted in the plasma processing apparatus illustrated in FIG. 7.

FIG. 9 is a cutaway perspective view illustrating an example of an insulative member, which may be adopted in the plasma processing apparatus illustrated in FIG. 7.

FIG. 10 is a view schematically illustrating a plasma processing apparatus according to still another exemplary embodiment.

FIG. 11 is an enlarged view illustrating a portion of the plasma processing apparatus according to still another exemplary embodiment.

FIG. 12 is a view illustrating a portion of a dielectric portion and a portion of an annular exhaust duct in a plasma processing apparatus according to still another exemplary embodiment.

Each of FIG. 13A and FIG. 13B is a partially enlarged view of a dielectric portion and an annular exhaust duct in a plasma processing apparatus according to still another exemplary embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, various exemplary embodiments will be described.

In an exemplary embodiment, a plasma processing apparatus is provided. The plasma processing apparatus includes a chamber, an introducer, and a choke structure. The introducer is installed such that electromagnetic waves are introduced into the chamber from the introducer. The choke structure is installed on the wall of the chamber. The choke structure is configured to suppress the propagation of electromagnetic waves downstream along the inner wall of the chamber from a location at which the chock structure is installed. The choke structure includes a slit-shaped first portion and a second portion. The first portion is connected to the space within the chamber. The second portion extends from the first portion in the wall of the chamber. The length of the second portion along a direction of an electric field of the electromagnetic waves in the second portion is longer than the length of the first portion along a direction of an electric field of the electromagnetic waves in the first portion.

In the above-described embodiment, the second portion is enlarged along the direction of the electric field of the electromagnetic waves with respect to the first portion. Accordingly, the strength of the electric field in the second portion becomes small. Therefore, according to the above-described embodiment, it is possible to suppress the discharge in the choke structure.

In an exemplary embodiment, the length of the second portion along the propagation direction of the electromagnetic waves in the second portion may be longer than the length of the first portion along the propagation direction of the electromagnetic waves in the first portion.

In an exemplary embodiment, the propagation direction of the electromagnetic waves in the first portion and the propagation direction of the electromagnetic waves in the second portion may be equal to each other.

In an exemplary embodiment, the choke structure may further include a dielectric portion installed within the first portion.

In an exemplary embodiment, the choke structure may further include a dielectric portion installed within the second portion.

In an exemplary embodiment, the choke structure may be installed on the side wall of the chamber. The side wall may include an annular exhaust duct. The annular exhaust duct provides an annular exhaust passage. The annular exhaust passage extends in the circumferential direction with respect to the central axis of the side wall and communicates with the space within the chamber. The first portion is formed in the wall that partitions and defines the annular exhaust duct, and extends in the circumferential direction with respect to the central axis. The second portion is the annular exhaust passage.

In an exemplary embodiment, the side walls of the chamber may include a first wall member and a second wall member. The first wall member extends above the first portion. The second wall member is separable from the first wall member and extends under the first portion of the choke structure. The first wall member and the second wall member may elastically sandwich the dielectric portion disposed between the first wall member and the second wall member.

In an exemplary embodiment, the side wall of the chamber may further include a third wall member and a fourth wall member. The third wall member is separable from the first wall member and the second wall member, and constitutes the annular exhaust duct together with the first wall member and the second wall member. The fourth wall member extends under the annular exhaust duct. The first wall member is installed on the second wall member and the third wall member, and partitions and defines an annular exhaust passage from the upper side. The second wall member extends inward with respect to the third wall member, and partitions and defines the annular exhaust passage from the lower side together with the third wall member. The second wall member may press the dielectric portion by a reaction force from at least one of the O-ring and the spiral spring gasket.

In an exemplary embodiment, the annular exhaust duct may include three or more concave portions. The three or more concave portions extend radially inward from the inner peripheral surface of the annular exhaust duct that partitions and defines the annular exhaust passage, and are arranged at equal intervals along the circumferential direction. The dielectric portion may include three or more convex portions disposed within the three or more concave portions.

In an exemplary embodiment, the dielectric portion provided within the first portion may extend into the annular exhaust passage.

In an exemplary embodiment, the dielectric portion may include first members and second members. The first members and the second members may be arranged alternately along the circumferential direction in the first portion. The first members may be fitted to the first portion. The thickness of each of the second members may be smaller than the thickness of each of the first members.

In an exemplary embodiment, the insulative member may have a ring shape. The insulative member may include a first cut portion extending from the inner peripheral side toward the outer peripheral side of the insulative member and a second cut portion extending from the outer peripheral side toward the inner peripheral side of the insulative member.

In an exemplary embodiment, the first cut portion and the second cut portion may be installed within an angle range of 90 degrees or less with respect to the center of the insulative member. That is, the first cut portion may be provided in the vicinity of the second cut portion paired therewith.

In an exemplary embodiment, the insulative member may provide multiple pairs of cut portions, each pair of which includes the first cut portion and the second cut portion. The multiple pairs of cut portions are arranged along the circumferential direction. The circumferential interval between the first and second cut portions in each of the pair of cut portions may be smaller than the circumferential interval of the multiple pairs of cut portions.

In an exemplary embodiment, the plasma processing apparatus may further include an elastic ring that presses the insulative member against the wall on which the first portion is formed.

In an exemplary embodiment, the choke structure may further include an insulative member installed to cover at least a portion the dielectric portion within the annular exhaust passage.

In an exemplary embodiment, the insulative member may cover a portion of the dielectric portion, except for the end portions of the dielectric portion, or may cover the entire dielectric portion within the annular exhaust passage.

In an exemplary embodiment, the insulative member may include plural portions separated from each other in the circumferential direction.

In an exemplary embodiment, the insulative member may have elasticity.

In an exemplary embodiment, the annular exhaust duct may include an outer wall that provides an opening. Another exhaust duct may be connected to the annular exhaust duct. The exhaust passage of another exhaust duct may be connected to the annular exhaust passage through the opening in the outer peripheral wall of the annular exhaust duct. The short-circuit portion may be provided within the opening to electrically connect a pair of edge portions, which partition and define the opening in the outer peripheral wall of the annular exhaust duct, to each other.

In an exemplary embodiment, the second portion may be a cavity. The pressure within the second portion may be set to be higher than the pressure in the space within the chamber.

Another exemplary embodiment also provides a plasma processing apparatus. The plasma processing apparatus includes a chamber, an introducer, and a choke structure. The introducer is provided such that electromagnetic waves are introduced into the chamber from the introducer. The choke structure is installed on the wall of the chamber. The choke structure is configured to suppress the propagation of electromagnetic waves downstream along the inner wall of the chamber from a location at which the chock structure is installed. The choke structure includes a slit-shaped first portion, a dielectric portion, and a second portion. The first portion is connected to the space within the chamber. The dielectric portion is installed within the first portion. The second portion extends from the first portion in the wall of the chamber. The second portion is a cavity and the pressure within the second portion is set to be higher than the pressure in the space in the chamber.

In an exemplary embodiment, the choke structure may provide a passage that allows the second portion to communicate with the atmospheric space outside the chamber.

In an exemplary embodiment, the plasma processing apparatus may further include a gas supplier configured to supply a gas to the second portion. The gas may be a fluorine-containing gas.

In an exemplary embodiment, the choke structure may be provided on the side wall of the chamber. The first portion and the second portion may extend in the circumferential direction with respect to the central axis of the side wall.

Hereinafter, various exemplary embodiments will be described in detail with reference to the drawings. In respective drawings, the same or corresponding components will be denoted by the same reference numerals.

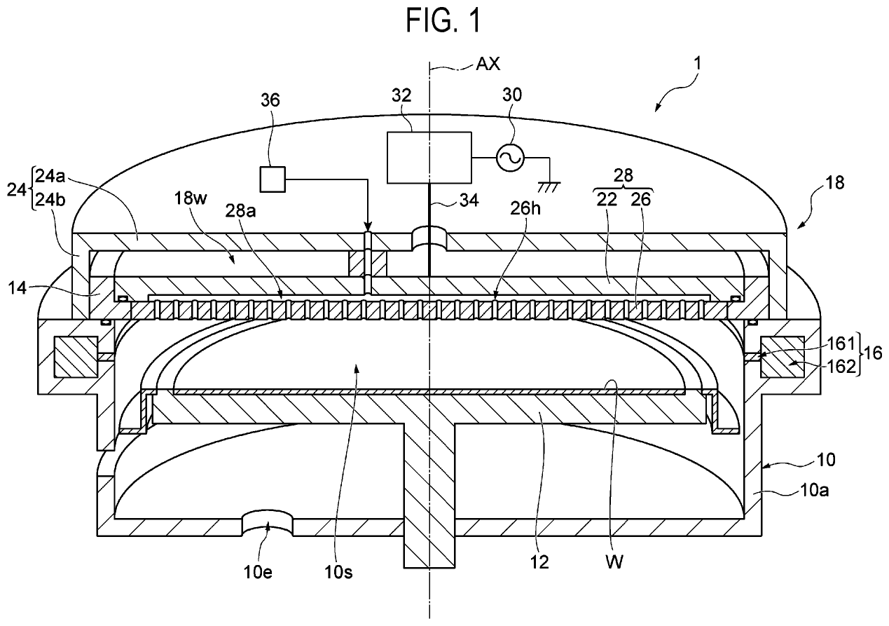

FIG. 1 is a view schematically illustrating a plasma processing apparatus according to an exemplary embodiment. The plasma processing apparatus 1 illustrated in FIG. 1 includes a chamber 10, an introducer 14, and a choke structure 16.

The chamber 10 provides therein a substrate processing space 10s. The chamber 10 is made of a metal such as aluminum and grounded. The chamber 10 may have a substantially cylindrical shape that is open at the upper end thereof. The central axis of each of the chamber 10 and the substrate processing space 10s is the axis AX. The chamber 10 may have a corrosion-resistant film on the surface thereof. The corrosion-resistant film may be an yttrium oxide film, an yttrium oxyfluoride film, an yttrium fluoride film, or a ceramic film including yttrium oxide, yttrium fluoride, or the like.

The bottom of the chamber 10 provides an exhaust port 10e. An exhaust apparatus is connected to the exhaust port 10e. The exhaust apparatus may include a vacuum pump such a dry pump and/or as a turbo molecular pump and an automatic pressure control valve.

The plasma processing apparatus 1 may further include a substrate support 12. The substrate support 12 is installed in the substrate processing space 10s. The substrate support 12 is configured to support a substrate W placed on the top surface thereof substantially horizontally. The substrate support 12 has a substantially disk-like shape. The central axis of the substrate support 12 is the axis AX.

The introducer 14 is provided so that electromagnetic waves are introduced into the chamber 10 from the introducer 14. The introducer 14 is made of a dielectric material such as quartz, aluminum nitride, or aluminum oxide. The introducer 14 may be substantially ring-shaped, and the central axis thereof may be the axis AX. The electromagnetic waves introduced into the chamber 10 from the introducer 14 are radio-frequency waves such as VHF waves or UHF waves. Electromagnetic waves are generated by a radio-frequency power source, which will be described later. The electromagnetic waves propagate to the introducer 14 through a waveguide part 18 and are introduced into the chamber from the introducer 14.

The waveguide part 18 provides a waveguide 18w. In an embodiment, the waveguide part 18 may include an upper electrode 22 and an upper wall 24. The upper electrode 22 is provided above the substrate support 12. The upper electrode 22 is made of a conductor such as, for example, aluminum, and has a substantially disk-like shape. The central axis of the upper electrode 22 is the axis AX.

The upper wall 24 is made of a conductor such as aluminum. The upper wall 24 is provided to cover the upper electrode 22, and the waveguide 18w is defined between the upper electrode 22 and the upper wall 24. The upper wall 24 may include an upper portion 24a and a side portion 24b. The upper portion 24a has a substantially disk-like shape, and its central axis is the axis AX. The upper portion 24a extends above the upper electrode 22 parallel to the top surface of the upper electrode 22. The waveguide 18w is defined between the top surface of the upper electrode 22 and the bottom surface of the upper portion 24a of the upper wall 24. The side portion 24b has a substantially cylindrical shape, and the central axis thereof is the axis AX. The side portion 24b extends downward from the peripheral edge portion of the upper portion 24a. The introducer 14 is provided to fill the space between the inner peripheral surface of the side portion 24b and the outer peripheral surface of the upper electrode 22. The upper wall 24 may be disposed on the side wall 10a so that the lower end of the side portion 24b is in contact with the side wall 10a of the chamber 10.

The plasma processing apparatus 1 further includes a radio-frequency power source 30 and a matcher 32. The radio-frequency power source 30 is configured to generate radio-frequency power. The electromagnetic waves introduced into the chamber 10 are generated based on the radio-frequency power generated by the radio-frequency power source 30. The radio-frequency power source 30 is connected to the upper electrode 22 via the matcher 32 and an electric line 34. The matcher 32 includes a matching circuit configured to match the impedance of the load of the radio-frequency power source 30 with the output impedance of the radio-frequency power source 30. The electric line 34 extends downward from the matcher 32 and is connected to the center of the top surface of the upper electrode 22. The electric line 34 may extend on the axis AX.

In an embodiment, the plasma processing apparatus 1 may further include a shower plate 26. The shower plate 26 is provided above the substrate support 12. The shower plate 26 has a substantially disk-like shape. The central axis of the shower plate 26 is the axis AX. The shower plate 26 may be made of a conductor such as aluminum. The space between the outer peripheral surface of the shower plate 26 and the inner peripheral surface of the side portion 24b of the upper wall 24 is filled with the introducer 14. The introducer 14 and the shower plate 26 are provided to close the upper end opening of the chamber 10.

The shower plate 26 includes gas holes 26h. The gas holes 26h penetrate the shower plate 26 in the plate thickness direction and open toward the substrate processing space 10s. An upper electrode 22 is installed on the shower plate 26. The upper electrode 22 and the shower plate 26 constitute a shower head 28. The upper electrode 22 and the shower plate 26 define a gas diffusion space 28a therebetween. The gas holes 26h extend downward from the gas diffusion space 28a.

The gas supplier 36 is connected to the gas diffusion space 28a. The gas output from the gas supplier 36 is supplied to the substrate processing space 10s via the gas diffusion space 28a and the gas holes 26h. The gas supplied by the gas supplier 36 is selected depending on the processing performed in the substrate processing space 10s. The gas supplied by the gas supplier 36 may include a film forming gas. The gas supplied by the gas supplier 36 may include a cleaning gas used for cleaning the wall surface within the chamber 10.

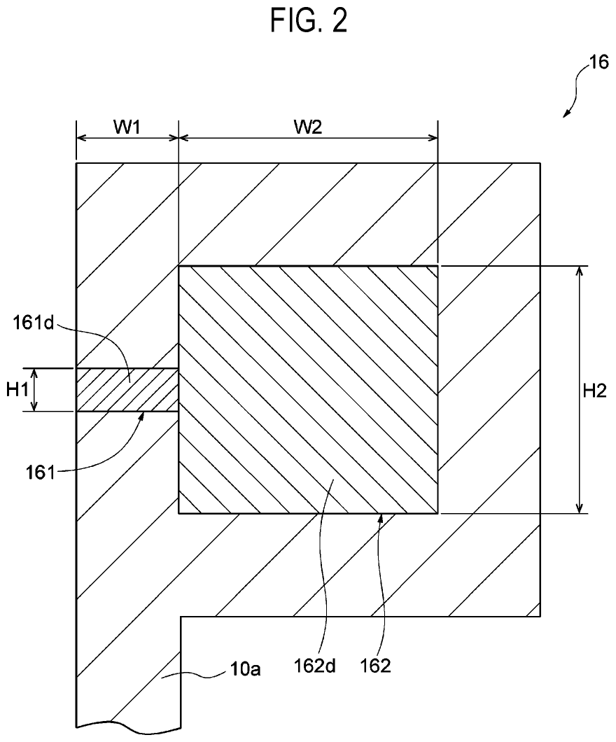

Hereinafter, reference will be made to FIG. 2 together with FIG. 1. FIG. 2 is a partially enlarged cross-sectional view of a choke structure in a plasma processing apparatus according to an exemplary embodiment. The choke structure 16 is provided on the wall of the chamber 10. The choke structure 16 is configured to suppress the propagation of electromagnetic waves downstream along the inner wall surface of the chamber 10 from the location at which the choke structure 16 is provided.

The choke structure 16 includes a slit-shaped first portion 161 and a second portion 162. The first portion 161 is connected to the substrate processing space 10s within the chamber 10. The second portion 162 extends from the first portion 161 in the wall of chamber 10. The second portion 162 may provide a space extending from the first portion 161 in the wall of the chamber 10.

The first portion 161 may include a dielectric portion 161d provided therein, that is, in the slit. The slit of the first portion 161 is filled with the dielectric portion 161d. In addition, the second portion 162 may include a dielectric portion 162d provided therein. The space of the second portion 162 is filled with the dielectric portion 162d. Each of the dielectric portion 161d and the dielectric portion 162d is made of a dielectric such as quartz, aluminum oxide, yttrium, silicon carbide, or aluminum nitride.

The length H2 of the second portion 162 along the direction of the electric field of electromagnetic waves in the second portion 162 is longer than the length H1 of the first portion 161 along the direction of the electric field of electromagnetic waves in the first portion 161. In each of the first portion 161 and the second portion 162, the direction of the electric field of electromagnetic waves is a direction orthogonal to the propagation direction of the electromagnetic waves.

In the plasma processing apparatus 1, the length W2 of the second portion 162 along the propagation direction of the electromagnetic waves in the second portion 162 may be longer than the length W1 of the first portion 161 along the propagation direction of the electromagnetic waves in the first portion 161. The sum of the length W1 and the length W2 is set such that the electromagnetic waves propagating along the inner wall surface of the chamber 10 is canceled by reflected waves returned from the choke structure 16. The reflected waves are generated since the electromagnetic waves are introduced from the first portion 161 into the choke structure 16 and reflected at the end surface (short-circuit surface) of the second portion 162 in the propagation direction. The sum of the length W1 and the length W2 may be set to, for example, about ¼ of the wavelength of the electromagnetic waves in the choke structure 16.

In an embodiment, the choke structure 16 is provided on the side wall 10a of the chamber 10, as illustrated in FIG. 1. The choke structure 16 is provided below the introducer 14. The first portion 161 and the slit thereof have a ring shape and extend in the circumferential direction with respect to the central axis of the side wall 10a, that is, the axis AX. The second portion 162 and the space therein have a ring shape and extend in the circumferential direction with respect to the axis AX. The second portion 162 extends radially outward with respect to the first portion 161. Each of the dielectric portion 161d and the dielectric portion 162d has a ring shape and extends in the circumferential direction with respect to the axis AX. In the plasma processing apparatus 1, the propagation directions of the electromagnetic waves in each of the first portion 161 and the second portion 162 are the radial direction with respect to the axis AX and are the same direction. In each of the first portion 161 and the second portion 162, the direction of the electric field of electromagnetic waves is the vertical direction.

In the plasma processing apparatus 1, the electromagnetic waves introduced into the chamber 10 from the introducer 14 propagate along the bottom surface of the shower plate 26 and excite the gas introduced into the chamber 10 from the gas holes 26h. As a result, plasma is generated from the gas just below the shower plate 26. The substrate W on the substrate support 12 is processed with chemical species from the generated plasma. The electromagnetic waves propagate downward (that is, downstream) along the side wall 10a of the chamber 10, but the propagation of the electromagnetic waves from the choke structure 16 downward (that is, downstream) is suppressed.

In the plasma processing apparatus 1 described above, the second portion 162 is expanded along the direction of the electric field of electromagnetic waves with respect to the first portion 161. Therefore, the strength of the electric field in the second portion 162 becomes small. Therefore, according to the plasma processing apparatus 1, it is possible to suppress the discharge in the choke structure 16. For example, even if there is a gap between the wall of the chamber 10 and the dielectric portion 162d due to the difference in thermal expansion coefficient between the wall of the chamber 10 and the dielectric portion 162d, the discharge in the choke structure 16 can be suppressed. By configuring the choke structure 16 to satisfy the relationship of lengths of H1<H2, the sum of the lengths W1 and the length W2 is shorter than the length of about ¼ of the wavelength of the electromagnetic waves in the choke structure 16. Therefore, it is possible to realize the miniaturization of the choke structure 16.

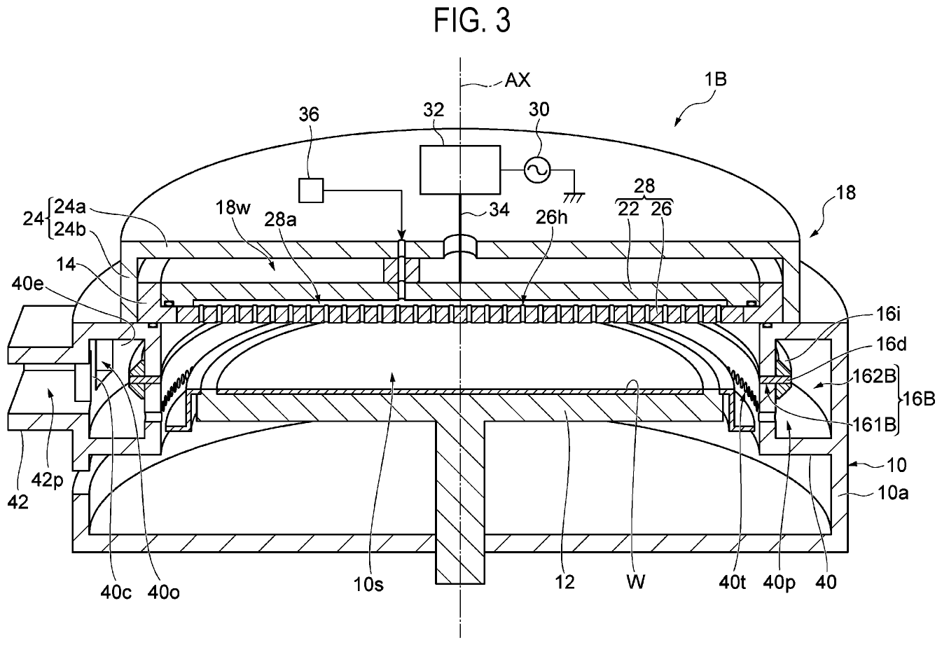

Hereinafter, a plasma processing apparatus according to another exemplary embodiment will be described with reference to FIG. 3. FIG. 3 is a diagram schematically showing a plasma processing apparatus according to another exemplary embodiment. Hereinafter, from the viewpoint of the difference between the plasma processing apparatus 1B illustrated in FIG. 3 and the plasma processing apparatus 1, the plasma processing apparatus 1B will be described.

The plasma processing apparatus 1B includes a choke structure 16B. The choke structure 16B is configured to suppress the propagation of electromagnetic waves downstream along the inner wall surface of the chamber 10 from the location at which the choke structure 16B is provided. The choke structure 16B is provided on the side wall 10a of the chamber 10. The side wall 10a includes an annular exhaust duct 40. The annular exhaust duct 40 provides an annular exhaust passage 40p therein. The annular exhaust duct 40 and the annular exhaust passage 40p have a ring shape and extend in the circumferential direction with respect to the axis AX. The inner peripheral wall of the annular exhaust duct 40 provides through holes 40t. The through holes 40t are arranged along the circumferential direction with respect to the axis AX. The annular exhaust passage 40p communicates with the substrate processing space 10s through the through holes 40t.

The choke structure 16B includes a first portion 161B and a second portion 162B. The first portion 161B is connected to the substrate processing space 10s within the chamber 10. The first portion 161B provides a slit. The slit of the first portion 161B is formed in the inner peripheral wall of the annular exhaust duct 40. The first portion 161B and the slit thereof have a ring shape and extend in the circumferential direction with respect to the axis AX. The second portion 162B extends from the first portion 161B in the wall of the chamber 10. In the plasma processing apparatus 1B, the second portion 162B is an annular exhaust passage 40p.

The length of the second portion 162B along the direction of the electric field of electromagnetic waves in the second portion 162B may be longer than the length of the first portion 161B along the direction of the electric field of electromagnetic waves in the first portion 161B. In each of the first portion 161B and the second portion 162B, the direction of the electric field of electromagnetic waves is a direction orthogonal to the propagation direction of the electromagnetic waves and is a vertical direction. The propagation directions of the electromagnetic waves in each of the first portion 161B and the second portion 162B are the radial direction with respect to the axis AX and are the same direction.

The length of the second portion 162B along the propagation direction of electromagnetic waves in the second portion 162B may be longer than the length of the first portion 161B along the propagation direction of electromagnetic waves in the first portion 161B. In the plasma processing apparatus 1B as well, the sum of the length of the first portion 161B and the length of the second portion 162B along the propagation direction of electromagnetic waves is set such that the electromagnetic waves propagating along the inner wall surface of the chamber 10 are canceled by the reflected waves returned from the choke structure 16B. The sum of the length of the first portion 161B and the length of the second portion 162B along the propagation direction of the electromagnetic waves may be set to, for example, about ¼ of the wavelength of the electromagnetic waves in the choke structure 16B.

The choke structure 16B further includes a dielectric portion 16d. The dielectric portion 16d is made of a dielectric such as quartz, aluminum oxide, yttrium, silicon carbide, and aluminum nitride. The dielectric portion 16d is provided at least in the slit of the first portion 161B. The slit of the first portion 161B is filled with the dielectric portion 16d. The dielectric portion 16d has a ring shape and extends in the circumferential direction with respect to the axis AX. The dielectric portion 16d extends into the annular exhaust passage 40p. That is, the dielectric portion 16d protrudes into the annular exhaust passage 40p from the slit of the first portion 161B.

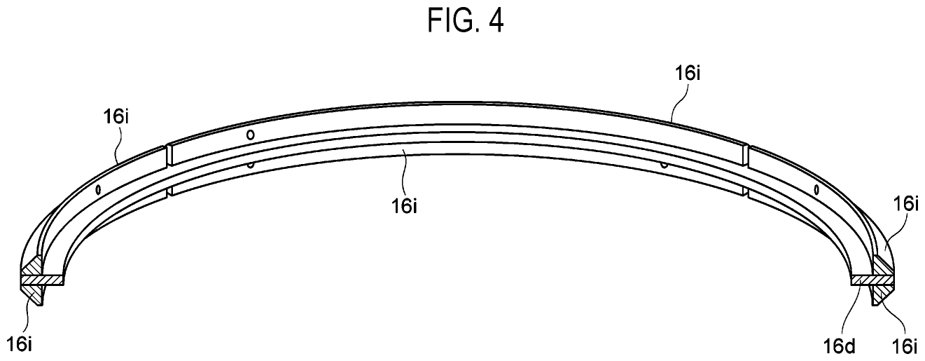

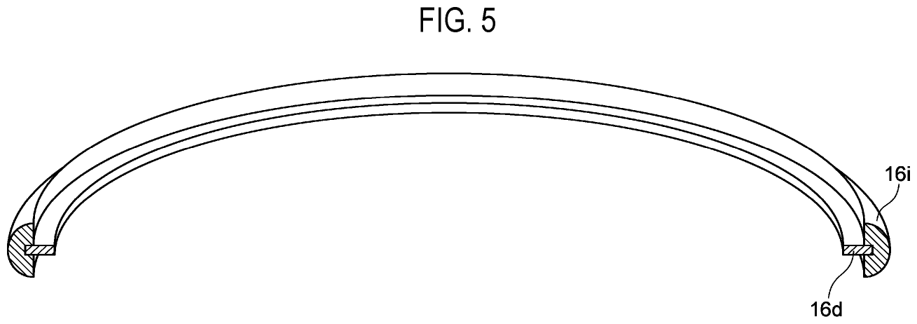

The choke structure 16B may further include an insulative member 16i. Hereinafter, reference will be made to FIG. 4 and FIG. 5 together with FIG. 3. FIG. 4 is a cutaway perspective view illustrating an example of an insulative member, which may be adopted in the plasma processing apparatus illustrated in FIG. 3. FIG. 5 is a cutaway perspective view illustrating another example of an insulative member, which may be adopted in the plasma processing apparatus illustrated in FIG. 3.

The insulative member 16i is made of an insulator such as quartz, aluminum oxide, yttrium, silicon carbide, aluminum nitride, or polytetrafluoroethylene. The insulative member 16i is provided to cover at least a portion of the dielectric portion 16d within the annular exhaust passage 40p. In the plasma processing apparatus 1B, the electric field strength of the electromagnetic waves within the annular exhaust passage 40p is reduced by the insulative member 16i.

In the example illustrated in FIGS. 3 and 4, the insulative member 16i covers a portion of the annular exhaust passage 40p except for the end portion of the dielectric portion 16d. In the example illustrated in FIGS. 3 and 4, the insulative member 16i includes plural portions separated from each other. Each of the plural portions of the insulative member 16i is fixed to the inner peripheral wall of the annular exhaust duct 40 by using, for example, a screw. Each of the plural portions of the insulative member 16i has a substantially triangular shape in an arbitrary cross section including the axis AX. That is, the length of each of the plural portions of the insulative member 16i in the height direction decreases as the distance from the axis AX increases.

The plural portions of the insulative member 16i constitute multiple pairs. The two portions included in each of the multiple pairs are arranged along the vertical direction, sandwiching the dielectric portion 16d therebetween. The multiple pairs of insulative members 16i are arranged along the circumferential direction. According to this example, since the plural portions of the insulative member 16i are separated from each other along the circumferential direction, even if the temperature of the insulative member 16i and the annular exhaust duct 40 becomes high, the occurrence of a gap between the insulative member 16i and the inner peripheral wall of the annular exhaust duct 40 is suppressed, so that it is possible to suppress the abnormal discharge generated in this gap.

In the example illustrated in FIG. 5, the insulative member 16i covers the entire dielectric portion 16d within the annular exhaust passage 40p. In the example illustrated in FIG. 5, the insulative member 16i has elasticity. The insulative member 16i is made of an elastic body such as fluororubber or silicone rubber. In the example illustrated in FIG. 5, the insulative member 16i has a substantially semicircular shape in an arbitrary cross section including the axis AX. In the example illustrated in FIG. 5, the insulative member 16i may be a single member. In this example as well, even if the temperature of the insulative member 16i and the annular exhaust duct 40 becomes high, the occurrence of a gap between the insulative member 16i and the inner peripheral wall of the annular exhaust duct 40 is suppressed, so that it is possible to suppress the abnormal discharge generated in this gap.

As illustrated in FIG. 3, the outer peripheral wall 40e of the annular exhaust duct 40 includes an opening 40o. Another exhaust duct 42 is connected to the annular exhaust duct 40. The exhaust duct 42 provides an exhaust passage 42p. The exhaust duct 42 and the exhaust passage 42p extend in a direction away from the chamber 10, for example, in a radial direction with respect to the axis AX. The exhaust passage 42p is connected to the annular exhaust passage 40p via the opening 40o. In addition, an exhaust apparatus is connected to the exhaust duct 42. The exhaust apparatus may include a vacuum pump such as a dry pump and/or a turbo molecular pump and an automatic pressure control valve.

A short-circuit portion 40c is provided in the opening 40o. The short-circuit portion 40c is made of a conductor such as aluminum, and has, for example, a rod shape. The short-circuit portion 40c electrically connects a pair of edge portions that partition and define the opening 40o, that is, the upper edge portion and the lower edge portion to each other. The short-circuit portion 40c separates the opening 40o into plural portions. The length of each of the plural portions of the opening 40o along the circumferential direction may be set to a length of 1/10 or less of the wavelength of the electromagnetic waves in the annular exhaust passage 40p. With the help of the short-circuit portion 40c, the outer peripheral wall 40e functions as a short-circuit surface against electromagnetic waves even in the portion that is provided with the opening 40o.

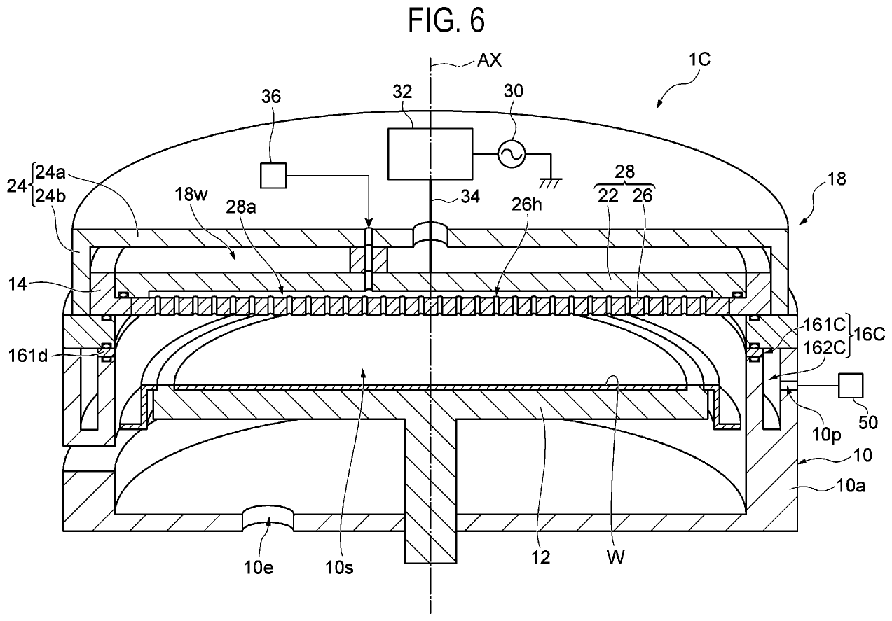

Hereinafter, a plasma processing apparatus according to another exemplary embodiment will be described with reference to FIG. 6. FIG. 6 is a view schematically illustrating a plasma processing apparatus according to yet another exemplary embodiment. Hereinafter, from the viewpoint of the difference between the plasma processing apparatus 1C illustrated in FIG. 6 and the plasma processing apparatus 1, the plasma processing apparatus 1C will be described.

The plasma processing apparatus 1C includes a choke structure 16C. The choke structure 16C is configured to suppress the propagation of electromagnetic waves downstream along the inner wall surface of the chamber 10 from the location at which the choke structure 16C is provided.

The choke structure 16C includes a slit-shaped first portion 161C and a second portion 162C. The first portion 161C is connected to the substrate processing space 10s within the chamber 10. The second portion 162C extends from the first portion 161C in the wall of the chamber 10. The second portion 162C may provide a cavity extending from the first portion 161C in the wall of the chamber 10.

The first portion 161C includes a dielectric portion 161d provided therein, that is, in the slit. The slit of the first portion 161C is filled with the dielectric portion 161d. The dielectric portion 161d is made of a dielectric such as quartz, aluminum oxide, yttrium, silicon carbide, and aluminum nitride.

In an embodiment, the choke structure 16C is provided on the side wall 10a of the chamber 10. The choke structure 16C is provided below the introducer 14. The first portion 161C and the slit thereof have a ring shape and extend in the circumferential direction with respect to the central axis of the side wall 10a, that is, the axis AX. The second portion 162C and the cavity therein have a ring shape and extend in the circumferential direction with respect to the axis AX. The second portion 162C extends radially outward with respect to the first portion 161C. The dielectric portion 161d has a ring shape and extends in the circumferential direction with respect to the axis AX. In the plasma processing apparatus 1C, the propagation direction of the electromagnetic waves in the first portion 161C is the radial direction with respect to the axis AX, and the propagation direction of the electromagnetic waves in the second portion 162C is a direction parallel to the axis AX. The sum of the length of the first portion 161C in the propagation direction of the electromagnetic waves and the length of the second portion 162C in the propagation direction of the electromagnetic waves may be set to, for example, about ¼ of the wavelength of the electromagnetic waves in the choke structure 16C.

The pressure within the second portion 162C (within the cavity therein) may be set to a pressure higher than the pressure in the substrate processing space 10s. In an embodiment, the side wall 10a of the chamber 10 may provide a passage 10p. The passage 10p may allow the cavity in the second portion 162C to communicate with the atmospheric space outside the chamber 10. In this case, since the pressure in the cavity of the second portion 162C becomes atmospheric pressure, the discharge in the second portion 162C can be suppressed. Alternatively, the gas supplier 50 may be connected to the passage 10p. The gas supplier 50 is configured to supply a gas to the cavity in the second portion 162C. The gas supplied by the gas supplier 50 to the cavity of the second portion 162C may be a fluorine-containing gas. In this case as well, the discharge in the second portion 162C can be suppressed.

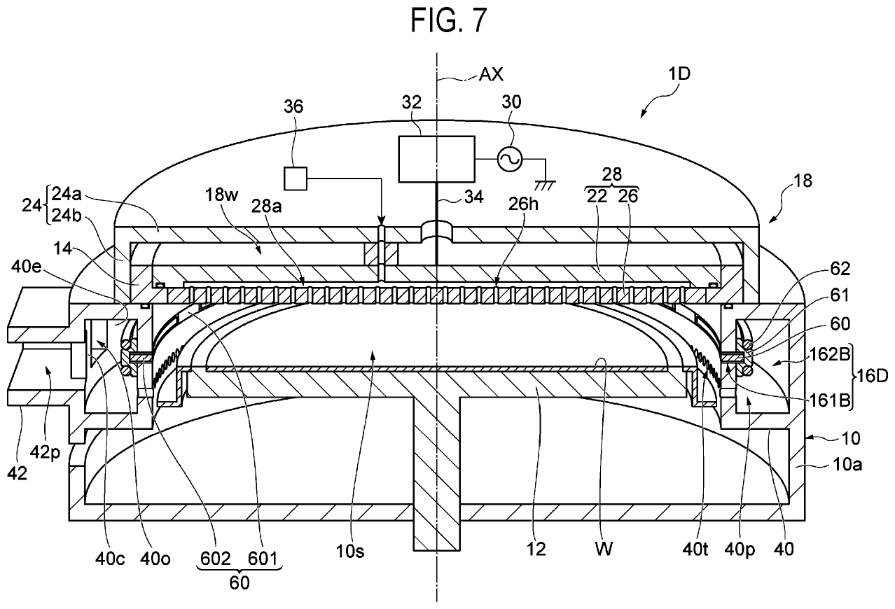

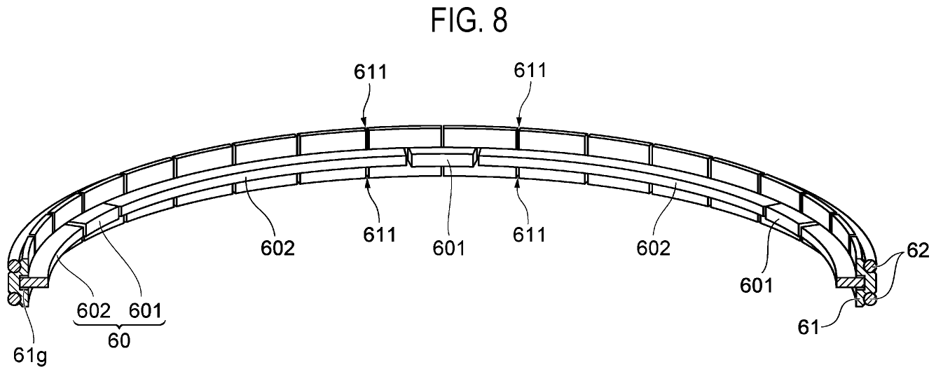

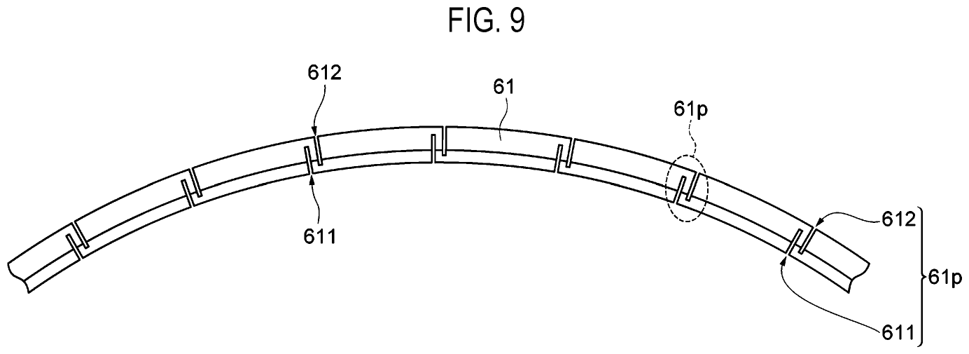

Hereinafter, the plasma processing apparatus according to still another exemplary embodiment will be described with reference to FIG. 7. FIG. 7 is a view schematically illustrating a plasma processing apparatus according to still another exemplary embodiment. Hereinafter, from the viewpoint of the difference between the plasma processing apparatus 1D illustrated in FIG. 7 and the plasma processing apparatus 1B, the plasma processing apparatus 1D will be described. Hereinafter, reference is made to FIGS. 8 to 9 in addition to FIG. 7. FIG. 8 is a cutaway perspective view illustrating an example of a dielectric portion, an insulative member, and an elastic ring that may be adopted in the plasma processing apparatus illustrated in FIG. 7. FIG. 9 is a cutaway perspective view illustrating an example of an insulative member, which may be adopted in the plasma processing apparatus illustrated in FIG. 7.

The plasma processing apparatus 1D includes a choke structure 16D. Like the choke structure 16B, the choke structure 16D includes a first portion 161B and a second portion 162B. The plasma processing apparatus 1D includes a dielectric portion 60, an insulative member 61, and at least one elastic ring 62 in place of the dielectric portion 16d and the insulative member 16i. Other configurations of the plasma processing apparatus 1D are the same as other configurations of the plasma processing apparatus 1B.

The dielectric portion 60 includes first members 601 and second members 602. The first members 601 and the second members 602 are alternately arranged along the circumferential direction within the first portion 161B (the slit thereof). That is, the dielectric portion 60 is divided in the circumferential direction. A slight gap may be interposed between each of the first members 601 and the second member 602 disposed adjacent thereto. The dielectric portion 60 protrudes into the annular exhaust passage 40p from the slit of the first portion 161B. The dielectric portion 60, that is, the first members 601 and the second members 602 are made of an insulator such as quartz, alumina, yttrium, silicon carbide, aluminum nitride, or polytetrafluoroethylene.

The first members 601 are fitted to the first portion 161B (the slit thereof). That is, each of the first members 601 has substantially the same thickness as the length of the first portion 161B (the slit thereof) in the vertical direction. Each of the first members 601 is vertically sandwiched by the inner peripheral wall which partitions and defines the first portion 161B (the slit thereof).

The thickness of each of the second members 602 is smaller than the thickness of each of the first members 601. The thickness of each of the second members 602 is smaller than the length of the first portion 161B (the slit thereof) in the vertical direction. The vertical length of the gap between each of the second members 602 and the inner peripheral wall which partitions and defines the first portion 161B (the slit thereof) is set to be long enough to prevent the penetration of plasma, for example, to be equal to or less than the sheath thickness. Each of the second members 602 is movable within the first portion 161B (the slit thereof)

The insulative member 61 is made of an insulator such as polytetrafluoroethylene. The insulative member 61 has a ring shape and extends in the circumferential direction within the annular exhaust passage 40p. The insulative member 61 covers the dielectric portion 60 within the annular exhaust passage 40p. Specifically, the insulative member 61 provides a groove 61g on the inner peripheral side thereof. Within the annular exhaust passage 40p, the dielectric portion 60 is disposed in the groove 61g. In the plasma processing apparatus 1D, the electric field strength of the electromagnetic waves within the annular exhaust passage 40p is reduced by the insulative member 61.

The insulative member 61 provides a first cut portion 611 and a second cut portion 612. The first cut portion 611 extends from the inner peripheral side toward the outer peripheral side of the insulative member 61. The second cut portion 612 extends from the outer peripheral side toward the inner peripheral side of the insulative member 61. The first cut portion 611 and the second cut portion 612 are provided within an angle range of 90 degrees or less with respect to the center of the insulative member 61. That is, the first cut portion 611 and the second cut portion 612 are provided close to each other in the circumferential direction and form a pair. The portion of the pair between the first cut portion 611 and the second cut portion 612 is configured to be easily deformable.

In an embodiment, the insulative member 61 may provide multiple pairs of cut portions 61p, in which each pair includes the first cut portion 611 and the second cut portion 612. The multiple pairs of cut portions 61p are arranged along the circumferential direction. The circumferential interval between the first cut portion 611 and the second cut portion 612 in each of the multiple pairs of cut portions 61p is smaller than the circumferential interval of the multiple pairs of cut portions 61p. The insulative member 61 is configured to be easily deformable in the portion between the first cut portion 611 and the second cut portion 612 in each of the multiple pairs of cut portions 61p.

In an embodiment, the plasma processing apparatus 1D may include at least one elastic ring 62, e.g., two elastic rings 62. Each of the two elastic rings 62 is, for example, an O-ring. The two elastic rings 62 extend in the circumferential direction within the annular exhaust passage 40p and are arranged along the vertical direction. The two elastic rings 62 press the insulative member 61 against the inner peripheral wall in which the first portion 161B is formed. This brings the inner peripheral surface of the insulative member 61 into close contact with the inner peripheral wall on which the first portion 161B is formed.

In the plasma processing apparatus 1D, the dielectric portion 60 is divided in the circumferential direction, and the second members 602 are movable. Accordingly, even when the temperature changes in the chamber 10, stress is not applied to the dielectric portion 60, and the dielectric portion 60 is prevented from cracking. In addition, since the insulative member 61 is expandable/contractible in the circumferential direction, it is possible to prevent a gap from occurring between the insulative member 61 and the inner peripheral wall of the annular exhaust duct 40 even when the temperature changes in the chamber 10.

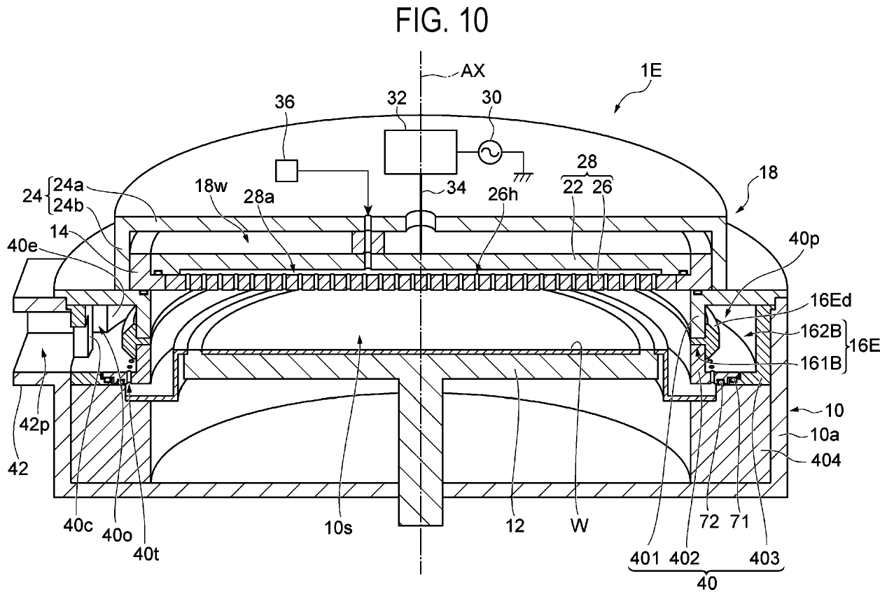

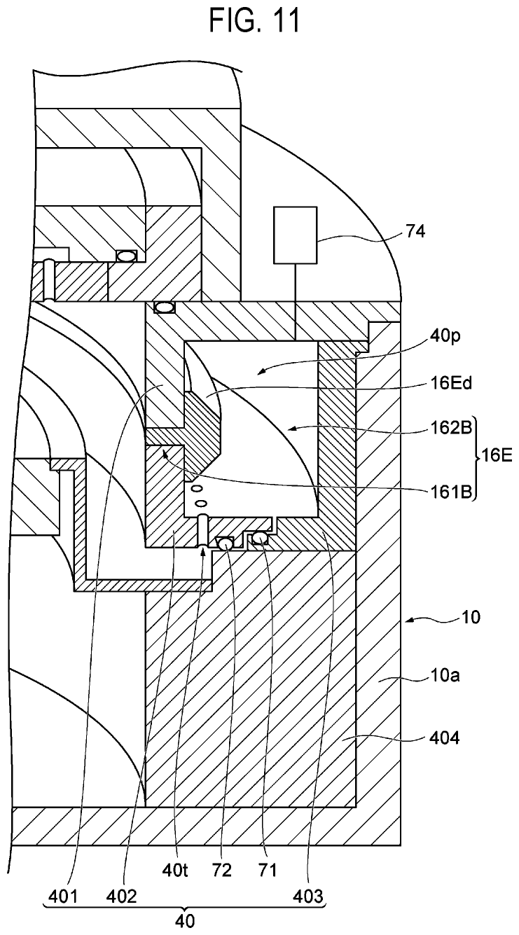

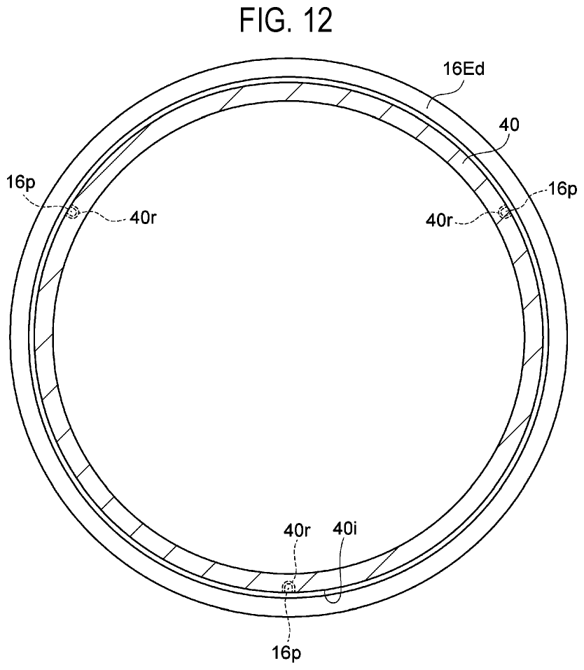

Hereinafter, a plasma processing apparatus according to still another exemplary embodiment will be described with reference to FIGS. 10 and 11. FIG. 10 is a view schematically illustrating a plasma processing apparatus according to still another exemplary embodiment. FIG. 11 is an enlarged view illustrating a portion of the plasma processing apparatus according to still another exemplary embodiment. Hereinafter, from the viewpoint of the difference between the plasma processing apparatus 1E illustrated in FIGS. 10 and 11 and the plasma processing apparatus 1B, the plasma processing apparatus 1E will be described.

The plasma processing apparatus 1E includes a choke structure 16E. Like the choke structure 16B, the choke structure 16E includes a first portion 161B and a second portion 162B. The plasma processing apparatus 1E includes a dielectric portion 16Ed in place of the dielectric portion 16d and the insulative member 16i.

The dielectric portion 16Ed is made of a dielectric such as quartz, aluminum oxide, yttrium, silicon carbide, and aluminum nitride. The dielectric portion 16Ed is substantially ring-shaped. A portion of the dielectric portion 16Ed, that is, a portion on the inner edge side is provided in the slit of the first portion 161B. The dielectric portion 16Ed extends into the annular exhaust passage 40p. The shape of the dielectric portion 16Ed in the annular exhaust passage 40p in an arbitrary cross section including the axis AX has a substantially triangular shape. That is, within the annular exhaust passage 40p, the length of the dielectric portion 16Ed in the height direction decreases as the distance from the axis AX increases.

In the plasma processing apparatus 1E, the side wall of the chamber 10 includes a first wall member 401 and a second wall member 402. The first wall member 401 is substantially ring-shaped and extends in the circumferential direction above the first portion 161B. The second wall member 402 is separable from the first wall member 401. The second wall member 402 has a substantially ring shape and extends in the circumferential direction under the first portion 161B. The first wall member 401 and the second wall member 402 partition and define a slit of the first portion 161B therebetween. The first wall member 401 and the second wall member 402 elastically sandwich the dielectric portion 16Ed disposed therebetween, that is, in the slit of the first portion 161B.

In an embodiment, the side wall of the chamber 10 may further include a third wall member 403 and a fourth wall member 404. The third wall member 403 is separable from the first wall member 401 and the second wall member 402, and constitutes the annular exhaust duct 40 together with the first wall member 401 and the second wall member 402. The third wall member 403 is substantially ring-shaped. The fourth wall member 404 extends under the annular exhaust duct 40. The first wall member 401, the second wall member 402, the third wall member 403, and the fourth wall member 404 are made of a metal, such as aluminum, and are grounded.

The first wall member 401 is installed on the second wall member 402 and the third wall member 403. The first wall member 401 partitions and defines the annular exhaust passage 40p from the upper side. The second wall member 402 extends radially inward with respect to the third wall member 403. The second wall member 402 partitions and defines the annular exhaust passage 40p from the lower side together with the third wall member 403. In the plasma processing apparatus 1E, through holes 40t that allow the annular exhaust passage 40p and the substrate processing space 10s to communicate with each other are formed in the bottom wall of the annular exhaust duct 40. Specifically, the through holes 40t are formed in the bottom wall portion of the second wall member 402. In the plasma processing apparatus 1E, the through holes 40t are arranged along the circumferential direction. As in the plasma processing apparatus 1B, the through holes 40t may be formed in the inner peripheral wall of the annular exhaust duct 40. The through holes 40t may have a width (or a diameter) of a size corresponding to the size of the distance from the connection position between the exhaust passage 42p and the annular exhaust passage 40p. In this case, the uniformity of exhaust in the circumferential direction is improved.

The plasma processing apparatus 1E may further include a spiral spring gasket 71 and an O-ring 72. The outer edge portion of the second wall member 402 extends above the inner edge portion of the third wall member 403, and the spiral spring gasket 71 is sandwiched between the outer edge portion of the second wall member 402 and the inner edge portion of the third wall member 403. A part of the spiral spring gasket 71 is disposed in a groove formed in the inner edge portion of the third wall member 403. Since the fourth wall member 404 abuts on the third wall member 403 from the lower side, the spiral spring gasket 71 shrinks in the height direction between the outer edge portion of the second wall member 402 and the inner edge portion of the third wall member 403. The second wall member 402 presses the dielectric portion 16Ed upward by the reaction force generated by the spiral spring gasket 71. As a result, the dielectric portion 16Ed disposed in the slit of the first portion 161B is elastically sandwiched between the first wall member 401 and the second wall member 402. The depth of the groove formed in the inner edge portion of the third wall member 403 is set such that the dielectric portion 16Ed is not damaged by the reaction force generated by the spiral spring gasket 71.

The O-ring 72 is sandwiched between the second wall member 402 and the fourth wall member 404. A part of the O-ring 72 is disposed in the groove formed in the second wall member 402. The O-ring 72 shrinks in the height direction by being sandwiched between the second wall member 402 and the fourth wall member 404. The second wall member 402 presses the dielectric portion 16Ed upward by the reaction force generated by the O-ring 72. As a result, the dielectric portion 16Ed disposed in the slit of the first portion 161B is elastically sandwiched between the first wall member 401 and the second wall member 402. The depth of the groove formed in the second wall member 402 is set such that the dielectric portion 16Ed is not damaged by the reaction force generated by the O-ring 72.

As illustrated in FIG. 11, in an embodiment, the plasma processing apparatus 1E may further include an ignition monitor 74. The ignition monitor 74 is configured to monitor the ignition of plasma in the annular exhaust passage 40p. The ignition monitor 74 may include, for example, an optical sensor that monitors the light emission of plasma. When the ignition monitor 74 detects the ignition of the plasma in the annular exhaust passage 40p, the plasma processing apparatus 1E may stop the generation of radio-frequency power by the radio-frequency power source 30.

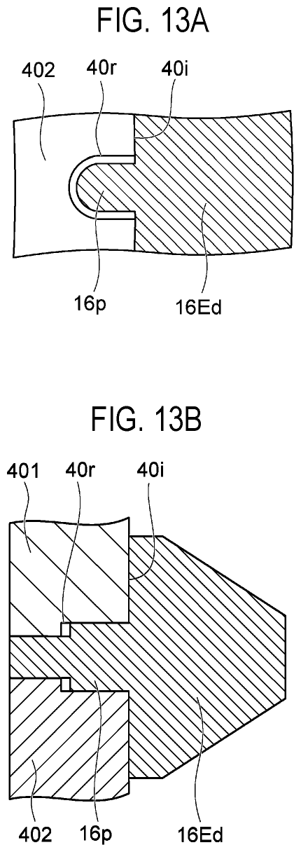

Hereinafter, reference will be made to FIGS. 12, 13A and 13B, FIG. 12 is a view illustrating a portion of a dielectric portion and a portion of an annular exhaust duct in a plasma processing apparatus according to still another exemplary embodiment. Each of FIG. 13A and FIG. 13B is a partially enlarged view of the dielectric portion and the annular exhaust duct in a plasma processing apparatus according to still another exemplary embodiment. FIG. 13A illustrates the cross-sectional shape of the dielectric portion in the cross section orthogonal to the axis AX, and FIG. 13B illustrates the cross-sectional shape of the dielectric portion in the cross section including the axis AX and the cross-sectional shape of a wall member of the annular exhaust passage.

In an embodiment, the annular exhaust duct 40 of the plasma processing apparatus 1E may provide three concave portions 40r. The three concave portions 40r extend radially inward from the inner peripheral surface 40i of the annular exhaust duct 40 which partitions and defines the annular exhaust passage 40p, and are disposed at equal intervals along the circumferential direction. In an embodiment, the three concave portions 40r may be partitioned and defined by and between a first wall member 401 and a second wall member 402. The annular exhaust duct 40 of the plasma processing apparatus 1E may provide three or more concave portions 40r.

The dielectric portion 16Ed may further include three convex portions 16p. The three convex portions 16p are disposed within the three concave portions 40r, respectively. The three convex portions 16p may have a U-shaped planar shape. The dielectric portion 16Ed may provide three or more convex portions 16p within the number of concave portions 40r.

According to the plasma processing apparatus 1E, the dielectric portion 16Ed is elastically sandwiched within the first portion 161B. Accordingly, even when the side wall of the chamber 10 and the wall members constituting the annular exhaust duct 40 are deformed due to thermal expansion or the like, damage to the dielectric portion 16Ed is suppressed. Furthermore, the occurrence of a gap between the dielectric portion 16Ed and the wall member constituting the annular exhaust duct 40 is suppressed.

With the plasma processing apparatus 1E, even when the side wall of the chamber 10 and the wall member constituting the annular exhaust duct 40 are deformed due to thermal expansion or the like, the change in the position of the dielectric portion 16Ed in the radial direction and the circumferential direction is suppressed due to the above-mentioned three convex portions 16p and three concave portions 40r. Accordingly, the concentricity between the dielectric portion 16Ed and the annular exhaust duct 40 is maintained.

The plasma processing apparatus 1E may include the dielectric portion 16d and the insulative member 16i illustrated in FIG. 4 or FIG. 5, or may include the dielectric portion 60, the insulative member 61, and the at least one elastic ring 62 illustrated in FIG. 8, in place of the dielectric portion 16Ed.

Although various exemplary embodiments have been described above, the present disclosure is not limited to the exemplary embodiments described above, and various additions, omissions, substitutions, and changes may be made. In addition, elements in different embodiments may be combined to form other embodiments.

For example, the choke structure according to various embodiments may be provided at any position on the wall of the chamber 10 as long as it is possible to suppress the propagation of electromagnetic waves to unnecessary locations within the chamber 10.

From the foregoing, it should be understood that various embodiments of the present disclosure have been described herein for purposes of illustration, and that various modifications can be made without departing from the scope and spirit of the present disclosure. Accordingly, the various embodiments disclosed herein are not intended to be limiting, and the true scope and spirit of the disclosure is indicated by the appended claims.

According to an exemplary embodiment, it is possible to suppress discharge in a choke structure of a plasma processing apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus comprising:
a chamber;
an introducer installed such that electromagnetic waves are introduced into the chamber from the introducer; and
a choke structure installed on a wall of the chamber and configured to suppress propagation of the electromagnetic waves downstream along an inner wall surface of the chamber from a location at which the choke structure is installed,
wherein the choke structure includes:
a first portion having a slit shape and connected to a space within the chamber; and
a second portion extending from the first portion in the wall of the chamber, and
wherein a length of the second portion along a direction of an electric field of the electromagnetic waves in the second portion is longer than a length of the first portion along a direction of an electric field of the electromagnetic waves in the first portion.

2. The plasma processing apparatus of claim 1, wherein a length of the second portion along a propagation direction of the electromagnetic waves in the second portion is longer a length of the first portion along a propagation direction of the electromagnetic waves in the first portion.

3. The plasma processing apparatus of claim 1, wherein a propagation direction of the electromagnetic waves in the first portion and a propagation direction of the electromagnetic waves in the second portion are equal to each other.

4. The plasma processing apparatus of claim 1, wherein the choke structure further includes a dielectric portion installed within the first portion.

5. The plasma processing apparatus of claim 4, wherein the choke structure further includes an additional dielectric portion installed within the second portion.

6. The plasma processing apparatus of claim 4, wherein the wall of the chamber is a side wall of the chamber,
wherein the side wall includes an annular exhaust duct that extends in a circumferential direction with respect to a central axis of the side wall and provides an annular exhaust passage that communicates with the space within the chamber,
wherein the first portion is formed on a wall that partitions and defines the annular exhaust duct, and extends in the circumferential direction with respect to the central axis, and
wherein the second portion is the annular exhaust passage.

7. The plasma processing apparatus of claim 6, wherein the side wall of the chamber further includes: a first wall member that extends above the first portion; and a second wall member that is separable from the first wall member and extends under the first portion, and
wherein the first wall member and the second wall member elastically sandwich the dielectric portion disposed between the first wall member and the second wall member.

8. The plasma processing apparatus of claim 7, wherein the side wall of the chamber further includes: a third wall member that is separable from the first wall member and the second wall member and constitutes the annular exhaust duct together with the first wall member and the second wall member; and a fourth wall member extending under the annular exhaust duct,
wherein the first wall member is installed on the second wall member and the third wall member, and partitions and defines the annular exhaust passage from an upper side,
wherein the second wall member extends inward with respect to the third wall member and partitions and defines the annular exhaust passage from a lower side together with the third wall member, and
wherein the second wall member presses the dielectric portion by a reaction force from at least one of an O-ring and a spiral spring gasket.

9. The plasma processing apparatus of claim 7, wherein the annular exhaust duct includes three or more concave portions extending radially inward from an inner peripheral surface of the annular exhaust duct that partitions and defines the annular exhaust passage, and disposed at equal intervals along the circumferential direction, and
wherein the dielectric portion includes three or more convex portions disposed within the three or more concave portions.

10. The plasma processing apparatus of claim 6, wherein the dielectric portion extends into the annular exhaust passage.

11. The plasma processing apparatus of claim 10, wherein the choke structure further includes an insulative member installed to cover at least a portion of the dielectric portion within the annular exhaust passage.

12. The plasma processing apparatus of claim 11, wherein the insulative member covers a portion of the annular exhaust passage except for an end portion of the dielectric portion or covers the entire dielectric portion within the annular exhaust passage.

13. The plasma processing apparatus of claim 11, wherein the insulative member includes plural portions separated from each other in the circumferential direction.

14. The plasma processing apparatus of claim 11, wherein the insulative member has a ring shape, and includes a first cut portion extending from an inner peripheral side toward an outer peripheral side of the insulative member and a second cut portion extending from the outer peripheral side toward the inner peripheral side of the insulative member.

15. The plasma processing apparatus of claim 14, wherein the first cut portion and the second cut portion are installed within an angle range of 90 degrees or less with respect to a center of the insulative member.

16. The plasma processing apparatus of claim 14, wherein the insulative member provides multiple pairs of cut portions, each pair including the first cut portion and the second cut portion,
wherein the multiple pairs of cut portions are arranged along the circumferential direction, and
wherein an interval between the first cut portion and the second cut portion in each of the multiple pairs of cut portions in the circumferential direction is smaller than an interval of the multiple pairs of cut portions in the circumferential direction.

17. The plasma processing apparatus of claim 11, further comprising:
an elastic ring configured to press the insulative member against the wall on which the first portion is formed.

18. The plasma processing apparatus of claim 11, wherein the insulative member has elasticity.

19. The plasma processing apparatus of claim 6, wherein the dielectric portion extends into the annular exhaust passage,
the dielectric portion includes first members and second members,
the first members and the second members are alternately arranged along the circumferential direction within the first portion,
the first members are fitted to the first portion, and
each of the second members has a thickness smaller than a thickness of each of the first members.

20. The plasma processing apparatus of claim 6, wherein the annular exhaust duct includes an outer peripheral wall that provides an opening,
wherein another exhaust duct is connected to the annular exhaust duct such that an exhaust passage of the another exhaust duct is connected to the annular exhaust passage through the opening, and
wherein a short-circuit portion that electrically connects a pair of edge portions, which partition and define the opening, to each other is formed within the opening.

21. The plasma processing apparatus of claim 4, wherein the second portion is a cavity, and a pressure within the second portion is set to a pressure higher than a pressure in the space within the chamber.

22. The plasma processing apparatus of claim 21, wherein the choke structure provides a passage that allows the second portion to communicate with an atmospheric space outside the chamber.

23. The plasma processing apparatus of claim 21, further comprising:
a gas supplier configured to supply a gas to the second portion.

24. The plasma processing apparatus of claim 23, wherein the gas is a fluorine-containing gas.

25. The plasma processing apparatus of claim 1, wherein the wall of the chamber is a side wall of the chamber, and
wherein the first portion and the second portion extend in a circumferential direction with respect to a central axis of the side wall.

26. A plasma processing apparatus comprising:
a chamber;
an introducer installed such that electromagnetic waves are introduced into the chamber from the introducer; and
a choke structure installed in a wall of the chamber and configured to suppress propagation of the electromagnetic waves downstream along an inner wall surface of the chamber from a location at which the choke structure is installed,
wherein the choke structure includes:
a first portion having a slit shape and connected to a space within the chamber;
a dielectric portion installed within the first portion; and
a second portion extending from the first portion in the wall of the chamber, and
wherein the second portion is a cavity, and a pressure within the second portion is set to a pressure higher than a pressure in the space within the chamber.
